(19) United States
(12) Patent Application Publication
(10) Pub. No.: US 2023/0307481 A1
(43) Pub. Date: Sep. 28, 2023

(54) PHOTODETECTOR ARRAY (PDA) METALLIZATION

(71) Applicant: Sensors Unlimited, Inc., Princeton, NJ (US)

(72) Inventors: John Liobe, Newton, NJ (US); Wei Zhang, Princeton, NJ (US)

(73) Assignee: Sensors Unlimited, Inc., Princeton, NJ (US)

(21) Appl. No.: 17/704,400

(22) Filed: Mar. 25, 2022

(51) Int. Cl. H01L 27/146; H04N 5/378; H04N 5/369

(52) U.S. Cl. CPC H01L 27/14643; H04N 5/378; H01L 27/14623; H04N 5/379; H01L 27/14636

(57) ABSTRACT

A photodetector array (PDA) system includes metal traces. A dielectric passivation layer defines a front side of a stack. An absorption layer is on a back side of the stack relative to the dielectric passivation layer. An array of pixels is included, each having a respective diffusion feature between the dielectric passivation layer and the absorption layer. The diffusion features are operatively connected to the absorption layer for photodetection. A metal trace runs between respective diffusion features. The metal trace is at a depth in the stack closer to the front side of the stack than the absorption layer. The dielectric passivation layer electrically insulates the metal trace from a front side surface of the stack.

### BACKGROUND

### 1. Field

The present disclosure relates to photodetector arrays (PDAs), and more particularly to PDAs for connection with readout integrated circuits (ROICs).

### 2. Description of Related Art

Power supply integrity is paramount in low-noise analog sensing applications, specifically in ROIC design. However, as additional functionality is included in every pixel pitch of ROICs, more and more components requiring interconnection are required in the ROIC designs. Even with modern CMOS processes with seven or more metal routing layers, real estate for realizing these interconnections is sparse prohibiting the creation of gridded and wide power supply traces to reduce IR (current times resistance) drop.

The conventional techniques have been considered satisfactory for their intended purpose. However, there is an ever-present need for improved systems and methods for PDA and ROIC functionality. This disclosure provides a solution for this need.

### SUMMARY

A photodetector array (PDA) system includes a dielectric passivation layer defining a front side of a material stack. An absorption layer is included as part of the material stack and is located deeper in the stack relative to the dielectric passivation layer. An array of pixels is included, each having a respective diffusion feature between the dielectric passivation layer and the absorption layer. The diffusion features are operatively connected to the absorption layer for photodetection. A metal trace runs between respective diffusion features. The metal trace is at a depth in the stack closer to the front side of the stack than the absorption layer. The dielectric passivation layer electrically insulates the metal trace from a front side surface of the stack. The metal trace is accessible for connection to a read out integrated circuit (ROIC).

The metal trace can be a first metal trace in an array of metal traces offset from an array defined by the pixel diffusion features. The metal trace can be layered on a stack of multiple sub-layers of the dielectric passivation layer. The metal trace can be separated from the front side surface of the stack by multiple sub-layers of the dielectric passivation layer. The metal trace can be embedded within multiple sub-layers of the dielectric passivation layer. The metal trace can include a stack of multiple sub-layers of metal material.

A second metal trace can run parallel to the first metal trace. The second metal trace can have a depth in the stack that is equal to that of the first metal trace. A portion of the dielectric layer can insulate between the first and second metal traces. It is also contemplated that the first metal trace can have a depth in the stack that is shallower than that of the second metal trace, wherein the first and second metal traces overly one another, and wherein a portion of the dielectric layer insulates between the first and second metal traces. These two metal traces can run at an angle relative to one another, e.g. perpendicular.

In a PIN type architecture, the dielectric passivation layer can be layered on a cap layer. The diffusion features can extend through the cap layer and into the absorption layer. In an APD type architecture, the dielectric passivation layer can be layered on a cap layer, and the diffusion features can be seated within the cap layer, which can be layered on a field control layer, which can be layered on a grading layer, which can be layered on the absorption layer. A contact layer or InP substrate can be layered on a back side surface of the absorption layer. An antireflective (AR) coating can be layered on a backside of the contact layer or InP substrate.

Each diffusion feature can be electrically connected to a hybridization bump configured to connect the respective diffusion feature to a readout integrated circuit (ROIC). An aperture can be defined through the dielectric passivation layer to the metal trace at a plurality of positions along the metal trace. A plurality of hybridization bumps can be each electrically connected to the metal trace through respective apertures through the dielectric passivation layer. The hybridization bumps of the diffusion components can form a first grid array. The hybridization bumps of the metal trace and of a plurality of parallel metal traces can form a second grid array that is offset from the first grid array. Both the hybridization bumps of the diffusion features and of the metal trace and plurality of metal traces can be planar with the PDA for connection to the ROIC.

A ROIC can be electrically connected to each of the hybridization bumps of the diffusion features and the metal trace. A power supply of the ROIC can connect to the metal trace through one of the hybridization bumps of the metal trace. The ROIC can include hybridization bumps that connect electrically with the hybridization bumps of the metal trace and diffusion features. It is also contemplated that the ROIC can include contact pads, wherein the hybridization bumps of the metal trace and diffusion features electrically connect directly to the contact pads of the ROIC.

A capacitor of the ROIC can be electrically connected to receive power from the power supply through the metal trace. An active component such as a transistor of the ROIC, and/or an active component of the ROIC, such as a capacitor, resistor, or inductor, can be electrically connected to receive power from the power supply through the metal trace.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a schematic cross-sectional side elevation view of an embodiment of a bumped photodetector array (PDA) system constructed in accordance with the present disclosure, showing the metal traces in a PDA with a p-type doped intrinsically doped, n-type doped (PIN) photodiode architecture;

FIG. 2 is a schematic cross-sectional side elevation view of an embodiment of a PDA system constructed in accordance with the present disclosure, showing the metal traces in a PDA with an avalanche photodiode (APD) architecture;

FIG. 3 is a layout view of the PDA system of FIG. 1, showing bump locations for the pixels and for the metal traces; and

FIG. 4 is a schematic block diagram view of the system of FIG. 1, showing how the metal traces can provide a route through the PDA for connecting the PDA to a readout integrated circuit (ROIC) in a focal plane array (FPA) system.

### DETAILED DESCRIPTION OF THE PREFERRED EMBODIMENTS

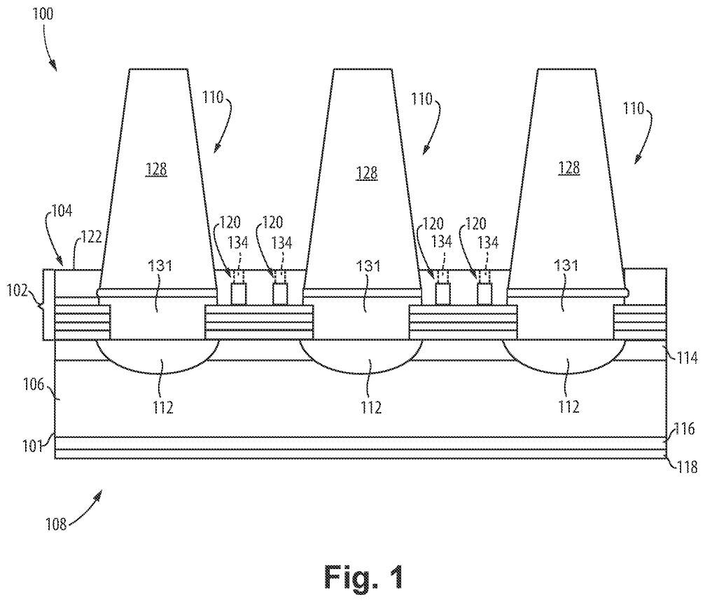

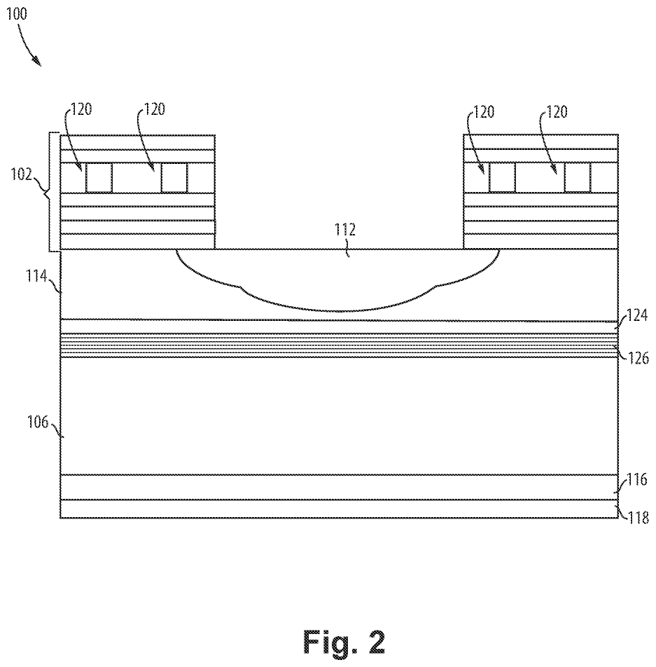

Reference will now be made to the drawings wherein like reference numerals identify similar structural features or aspects of the subject disclosure. For purposes of explanation and illustration, and not limitation, a partial view of an embodiment of a focal plane array (FPA) system in accordance with the disclosure is shown in FIG. 1 and is designated generally by reference character 100. Other embodiments of systems in accordance with the disclosure, or aspects thereof, are provided in FIGS. 2-4, as will be described. The systems and methods described herein can be used to provide electrical pathways through a PDA for interconnecting components of a readout integrated circuit (ROIC). This can leave more room in the ROIC for functional components in the ROIC.

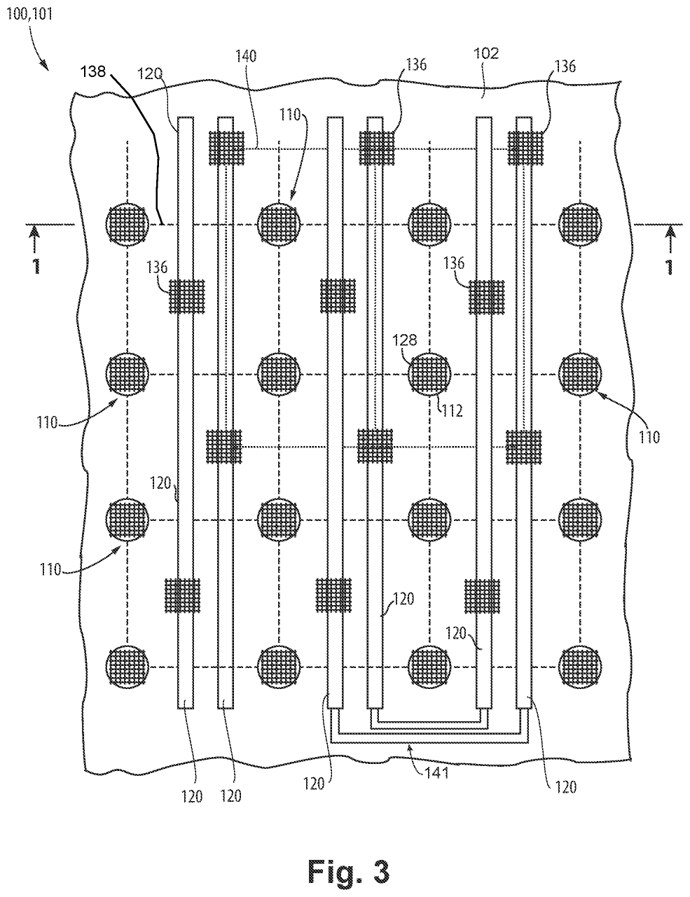

The FPA system 100 includes a dielectric passivation layer 102 defining a front side 104 of a photodiode array (PDA) stack 101. The dielectric passivation layer 102 includes multiple layers of oxides and nitrides. The PDA stack 101 in FIG. 1 has a PIN architecture, including an i-InGaAs absorption layer 106 is on a back side 108 of the stack 101 relative to the dielectric passivation layer 102. An array of pixels 110 is included (only three pixels are shown in FIG. 1, however those skilled in the art will readily appreciate that the FPA system 100 can include any suitable number of pixels 110, patterned in any suitable array, e.g. as shown in FIG. 3, and that each pixel includes a photodiode and surrounding area). Each pixel 110 includes a respective diffusion feature 112 between the dielectric passivation layer 102 and the absorption layer 106. The diffusion features 112 are operatively connected to the absorption layer 106 for photodetection. The dielectric passivation layer 102 is layered on an InP cap layer 114. The diffusion features 112 extend through the cap layer 114 and into the absorption layer 106. An n-InP contact layer 116 or substrate is layered on a back side surface of the absorption layer 106. An optional antireflective (AR) coating 118 is layered on a backside of the contact layer 116.

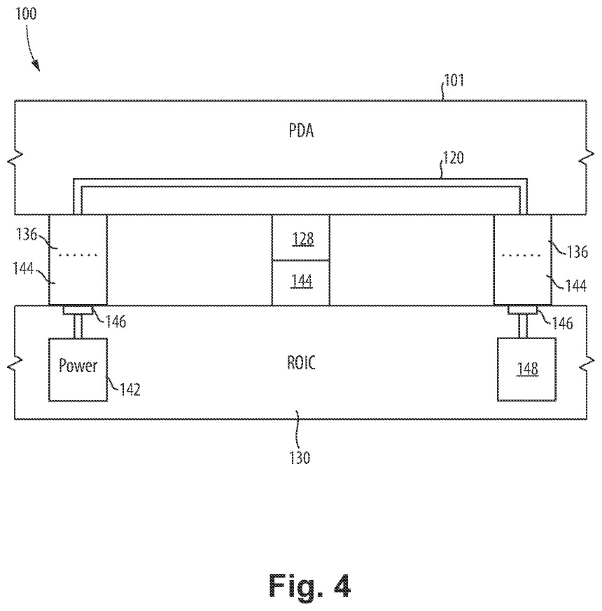

With continued reference to FIG. 1, a plurality of parallel metal traces 120 run between respective diffusion features 112. The metal traces 120 are at a depth in the stack closer to the front side 104 of the stack than the absorption layer 106. The dielectric passivation layer 102 electrically insulates the metal traces 120 from the front side surface 122 of the stack. The metal traces 120 are layered on a stack of multiple sub-layers of the dielectric passivation layer 102, and so are separated from the cap layer 114. The metal traces 120 are separated from the front side surface 122 of the stack by multiple sub-layers of the dielectric passivation layer 102. The metal traces 120 are embedded within multiple sub-layers of the dielectric passivation layer 102, which provides electrical isolation between the metal traces 120 themselves, as well as between the metal traces 120 and the pixel diffusion features 112 as well as between the pixel diffusion features 112 and the metal contacts 131 of one pixel and of another pixel. Each metal trace 120 can include a stack of multiple sub-layers of metal material. While there is a pair of side-by-side metal traces 120 between each adjacent pair of pixels 110 in FIG. 1, it is also contemplated that the pairs of metal traces could instead be one on top of the other, with intervening dielectric sub-layers separating them, which can allow for the metal traces to run at angles such as perpendicular to one another. In this case interconnecting the metal traces to a ROIC 130 (labeled in FIG. 4) could be facilitated if the metal traces 120 at different depths ran different directions from one another, while being parallel in with respect to the plane of the PDA stack 101. Although shown and described with two metal traces 120 between each pixel 110, those skilled in the art will readily appreciate that any suitable number of metal traces 120 can be included between pixels 110 without departing from the scope of this disclosure.

While FIG. 1 shows the stack of the FPA system 100 in a PIN type architecture, it is also contemplated that an avalanche photodiode (APD) type architecture can also be used, as shown in FIG. 2 where like reference numbers refer to like elements as described above with respect to FIG. 1. In the APD architecture, the diffusion layer 112 is seated within the cap layer 114 (without passing all the way through the cap layer 114. The cap layer 114 is layered on a field control layer 124, which is layered on a grading layer 126, which is layered on the absorption layer 106. Otherwise, the location and function of the metal traces 120 can be similar whether an APD architecture or PIN architecture is used.

With reference now to FIG. 3, each diffusion feature 112 is electrically connected to a hybridization bump 128 through a metal contact 131. The bumps 128 are configured to connect the respective diffusion features 112 to a readout integrated circuit (ROIC) 130, which is labeled in FIG. 4. An aperture 134 (labeled in FIG. 1) is defined through the dielectric passivation layer 102 to each metal trace at a plurality of positions along the metal trace 120. A plurality of hybridization bumps 136 are each electrically connected to the metal traces 120 through respective apertures 134 (shown in FIG. 1). The hybridization bumps 128 of the diffusion components 112 form a first grid array 138, indicated by dashed lines in FIG. 3. The hybridization bumps 136 of each of the metal traces 120 form a second grid array 140, indicated with dots in FIG. 3, that is offset from the first grid array 138. For sake of clarity, the grid pattern 140 is only shown for one of the metal traces 120 in FIG. 3. Optionally, the straight portions of each metal trace 120 can be connected by u-turn portions 141, e.g. at one end of the PDA pixel array as shown in FIG. 3, which can be useful, e.g. for test features on a PDA layer, for redundant connection between signal traces if a ROIC is designed as such, or the like.

With reference now to FIG. 4, a ROIC 130 can be electrically connected to each of the hybridization bumps 136 the metal traces 120. The ROIC 130 is also connected to the hybridization bumps 128 of the diffusion areas 112. A power supply 142 of the ROIC 130 connects to the metal trace 120 through one of the hybridization bumps 136 of the metal trace 120. The ROIC 130 optionally is connected by a double sized hybridization that includes hybridization bumps 144 of its own that connect electrically with the hybridization bumps 128/136 of the PDA stack 101 (labeled in FIG. 3). The ROIC 130 includes contact pads 146, wherein optionally in a single sided hybridization, the hybridization bumps 128/136 of the PDA stack 101 electrically connect directly to the contact pads 146 of the ROIC 130.

A plurality of functional components 148 of the ROIC 130 are electrically connected to receive power from the power supply 142 through the metal traces 120. Active devices such as transistors and passive devices such as capacitors, resistors, and inductors of the ROIC 130 can be electrically connected to receive power from the power supply 142 through the metal trace 120. In this way, two ROIC components can be electrically connected without needing to provide real estate on the ROIC 130 for the metal traces 120 that connect the two components. This can be used, for example to provide global power distribution from the power source 142 to other functional components in the ROIC 130.

A considerable potential benefit of systems and methods as disclosed herein is the additional global routing capability on the ROIC afforded by having additional metal layers on the photodetector array (PDA) layer. The additional global routing has several potential benefits. It can be utilized for signal interconnection and propagation across the integrated assembly. Additionally, it can be utilized to grid power supply lines to reduce the resistance of said supply lines improving supply integrity across the pixel array. This is an advance on a very important problem in image sensors. Reducing the resistance of the pixel power supply is often the last consideration in designing imaging arrays because one first needs to ensure that the desired pixel functionality is realized through the interconnection of all of the pixel circuitry and signal distribution across the pixel array. Power supply integrity is a secondary consideration although a high resistance power grid can affect pixel-level performance.

The methods and systems of the present disclosure, as described above and shown in the drawings, provide for electrical pathways through a PDA for interconnecting components of a ROIC, which can leave more room in the ROIC for functional components in the ROIC. While the apparatus and methods of the subject disclosure have been shown and described with reference to preferred embodiments, those skilled in the art will readily appreciate that changes and/or modifications may be made thereto without departing from the scope of the subject disclosure.

1. A photodetector array (PDA) system comprising:
a dielectric passivation layer defining a front side of a stack;
an absorption layer on a back side of the stack relative to the dielectric passivation layer;
an array of pixels, each including a respective diffusion feature between the dielectric passivation layer and the absorption layer, wherein the respective diffusion features are operatively connected to the absorption layer for photodetection;
a metal trace running between the respective diffusion features, wherein the metal trace is at a depth in the stack closer to the front side of the stack than the absorption layer, and wherein the dielectric passivation layer electrically insulates the metal trace from a front side surface of the stack, wherein the metal trace is accessible for connection to a read out integrated circuit (ROIC).

2. The system as recited in claim 1, wherein the metal trace is a first metal trace, and further comprising a second metal trace running parallel to the first metal trace, wherein the second metal trace has a depth in the stack that is equal to that of the first metal trace, wherein a portion of the dielectric passivation layer insulates between the first and second metal traces.

3. The system as recited in claim 1, wherein the metal trace is a first metal trace, and further comprising a second metal trace, wherein the first metal trace has a depth in the stack that is shallower than that of the second metal trace, wherein the first and second metal traces overly one another, and wherein a portion of the dielectric passivation layer insulates between the first and second metal traces.

4. The system as recited in claim 1, wherein the dielectric passivation layer is layered on a cap layer, wherein the respective diffusion features extend through the cap layer and into the absorption layer.

5. The system as recited in claim 1, wherein the dielectric passivation layer is layered on a cap layer, wherein the respective diffusion features are seated within the cap layer, which is layered on a field control layer, which is layered on a grading layer, which is layered on the absorption layer.

6. The system as recited in claim 1, further comprising a contact layer, or InP substrate, layered on a back side surface of the absorption layer.

7. The system as recited in claim 6, further comprising an antireflective (AR) coating layered on a backside of the contact layer, or InP substrate.

8. The system as recited in claim 1, wherein the metal trace is layered on a stack of multiple sub-layers of the dielectric passivation layer.

9. The system as recited in claim 1, wherein the metal trace is separated from the front side surface of the stack by multiple sub-layers of the dielectric passivation layer.

10. The system as recited in claim 1, wherein the metal trace is embedded within multiple sub-layers of the dielectric passivation layer; and/or wherein the metal trace includes a stack of multiple sub-layers of metal material.

11. The system as recited in claim 1, wherein the metal trace is a first metal trace in an array of metal traces offset from an array defined by the respective diffusion features.

12. The system as recited in claim 1, wherein each respective diffusion feature is electrically connected to a diffusion feature hybridization bump configured to connect the respective diffusion feature to the readout integrated circuit (ROIC), and further comprising:
an aperture through the dielectric passivation layer to the metal trace at a plurality of positions along the metal trace;
a plurality of trace hybridization bumps each electrically connected to the metal trace through respective apertures through the dielectric passivation layer.

13. The system as recited in claim 12, further comprising the ROIC, wherein the ROIC is electrically connected to each of the hybridization bumps of the diffusion features and the metal trace.

14. The system as recited in claim 13, wherein the ROIC includes ROIC hybridization bumps that connect electrically with the diffusion feature hybridization bumps and with the trace hybridization bumps.

15. The system as recited in claim 13, wherein the ROIC includes contact pads, wherein the hybridization bumps of the metal trace and respective diffusion features electrically connect directly to the contact pads of the ROIC.

16. The system as recited in claim 12, wherein the diffusion feature hybridization bumps form a first grid array, and wherein the trace hybridization bumps and of a plurality of parallel metal traces form a second grid array that is offset from the first grid array, wherein both the diffusion feature hybridization bumps and the trace hybridization bumps are planar with the PDA for connection to the ROIC.

17. The system as recited in claim 1, further comprising a respective metal contact electrically connected to each respective diffusion feature, wherein the metal trace runs between the respective metal contacts, wherein the dielectric passivation provides electrical isolation between the metal trace and the respective metal contacts.
